(19) United States
(12) Patent Application Publication
(10) Pub. No.: US 2024/0347324 A1
(43) Pub. Date: Oct. 17, 2024

(54) METHOD FOR ORGANIC EFFLUENT ABATEMENT

(71) Applicant: Applied Materials, Inc., Santa Clara, CA (US)

(72) Inventors: Ryan T. DOWNEY, San Jose, CA (US); Joseph T. VAN GOMPEL, Santa Clara, CA (US); James L'HEUREUX, Santa Clara, CA (US)

(21) Appl. No.: 18/429,086

(22) Filed: Jan. 31, 2024

Related U.S. Application Data
(60) Provisional application No. 63/495,450, filed on Apr. 11, 2023.

(51) Int. Cl. H01J 37/32; C23C 16/44

(52) U.S. Cl. CPC H01J 37/32844; C23C 16/4412; H01J 2237/3321

(57) ABSTRACT

A method and system for treating effluent from a processing chamber are disclosed herein. In one example, the effluent is treated by flowing a hydrocarbon processing gas into a processing chamber having a substrate disposed therein, performing a process on the substrate using the hydrocarbon processing gas that creates organic byproducts, exhausting the organic byproducts from the processing chamber into a foreline having an abatement reaction zone, and treating the organic byproducts in the abatement reaction zone. The treating of the organic byproducts comprises mixing a disassociated oxygen-containing gas and the organic byproducts in the abatement reaction zone, and forming at least carbon monoxide and carbon dioxide from the mixture of the disassociated oxygen-containing gas and the organic byproducts.

### RELATED APPLICATIONS

This application claims benefit from U.S. Provisional Application Ser. No. 63/495,450, filed Apr. 11, 2023, the contents of which is incorporated by reference in its entirety.

### BACKGROUND

### Field

Embodiments of the present disclosure generally relate to abatement for semiconductor processing equipment. More particularly, embodiments of the present disclosure relate to techniques for abating organic compounds present in the effluent of semiconductor processing equipment.

### Description of the Related Art

Effluent produced during semiconductor manufacturing processes include many compounds which must be abated or treated before disposal, due to equipment longevity and safety concerns. Among these compounds are organics, which are a residual of, for example, a carbon deposition process. In-line plasma sources (IPS) or remote plasma sources (RPS) have been used for abatement of effluent gases. However, abating organic gases used in semiconductor processing remains a challenge as downstream equipment life is significantly reduced as technology advancements in carbon deposition processes add more and more organics into the effluent exhaust line. Such gases and particulate matter created from the gases depositing within the effluent exhaust line are harmful to equipment and the failure of equipment may pose safety concerns. Accordingly, what is needed in the art is an improved abatement technique for organic gases.

### SUMMARY

A method and system for treating effluent from a processing chamber are disclosed herein. In one example, the effluent is treated by flowing a hydrocarbon processing gas into a processing chamber having a substrate disposed therein, performing a process on the substrate using the hydrocarbon processing gas that creates organic byproducts, exhausting the organic byproducts from the processing chamber into a foreline having an abatement reaction zone, and treating the organic byproducts in the abatement reaction zone. The treating of the organic byproducts comprises mixing a disassociated oxygen-containing gas and the organic byproducts in the abatement reaction zone, and forming at least carbon monoxide and carbon dioxide from the mixture of the disassociated oxygen-containing gas and the organic byproducts.

In another example, a vacuum chamber abatement system comprises, a vacuum chamber having an interior volume, an exhaust port coupled to the interior volume, a foreline connecting the exhaust port to a remote plasma source, a valve disposed between the remote plasma source and the foreline, a vacuum pump coupled to the foreline, the remote plasma source disposed upstream of the vacuum pump, an RF power source coupled to the remote plasma source, an inert gas source coupled to the remote plasmas source, an oxygen gas source coupled to the remote plasma source, a foreline pressure gas source coupled to the foreline disposed between the remote plasma source and the vacuum pump, and a controller coupled to the chamber. The remote plasma source is disposed about 20 cm to about 40 cm length from the foreline. The controller is configured to flow a hydrocarbon precursor gas into the vacuum chamber interior for carbon deposition on a substrate within, perform a carbon deposition process on the substrate thereby creating organic byproducts, exhaust the organic byproducts from the vacuum chamber interior and into a foreline through the exhaust port, and treat the organic byproducts. The organic byproducts being silicon-free and comprising propene. Treating the organic byproducts comprises flowing an oxygen gas into a remote plasma source at a molar ratio of 2:9 (oxygen gas:organic byproduct), mixing an argon gas with the oxygen gas at a ratio of 0.5 percent inert to 250 percent, forming a plasma to create oxygen and argon radicals, mixing the oxygen and argon radicals with the organic byproducts in the foreline, and disassociating the organic byproducts into a fluid comprising carbon monoxide and carbon dioxide.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a schematic side view of a plasma abatement process system having an in-line plasma reactor.

FIG. 1B is a schematic side view of a plasma abatement process system having a remote plasma reactor.

FIG. 2 is a flow diagram of a method for treating effluent from a process chamber.

FIG. 3 is an illustration of a vacuum process chamber according to one embodiment.

To facilitate understanding, identical reference numerals have been used, where possible, to designate identical elements that are common to the figures. It is contemplated that elements and features of one embodiment may be beneficially incorporated in other embodiments without further recitation.

Many of the details, dimensions, angles, and other features shown in the Figures are merely illustrative of particular implementations. Accordingly, other implementations can have other details, components, dimensions, angles, and features without departing from the spirit or scope of the present disclosure. In addition, further implementations of the disclosure can be practiced without several of the details described below.

### DETAILED DESCRIPTION

Embodiments disclosed herein include abatement methods for treating organic materials present in an effluent exiting a processing chamber such as a deposition chamber, an etch chamber, or other vacuum processing chamber. Generally, the abatement methods employ a plasma abatement system to react the effluent exiting a processing chamber into a more benign form of exhaust. The abatement process includes receiving effluent exiting from the processing chamber in an abatement reaction zone of a foreline, mixing the effluent received in the abatement reaction zone with disassociated reactive gases, and reacting the reactive gases and the effluent within the abatement reaction zone. In some examples, a plasma chamber may be disposed in-line with the foreline to define the abatement reaction zone. In other example, the reactive gases are disassociated in a remote plasma source (RPS), then flowed into the abatement reaction zone of the foreline for mixing and reacting with the effluent. The disassociated reactive gases readily react with the organic materials within the effluent to substantially reduce untreated organic effluent deposits of amorphous organic material within the foreline or downstream equipment. Amorphous organic material deposits often contribute to premature failure of downstream equipment, such as pumps, valves and the like, and can also pose a safety concern for personnel. Thus, the organic abatement process disclosed herein beneficially increases the conversion efficiency of organic materials within the effluent into more benign forms, resulting in extended equipment life, longer maintenance intervals, and safer operating conditions.

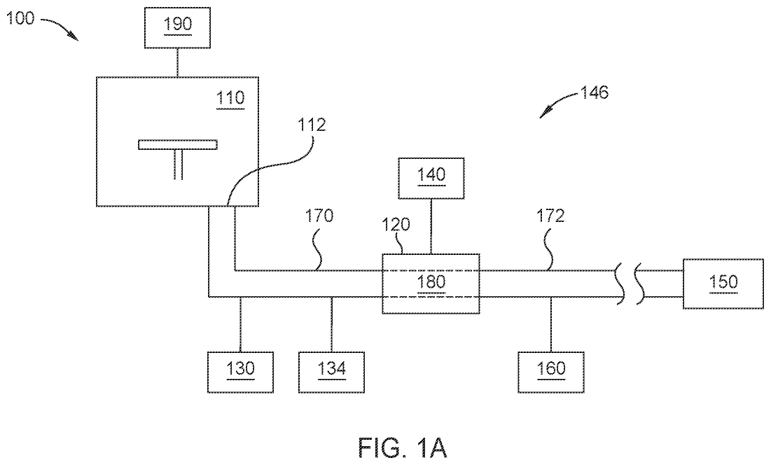

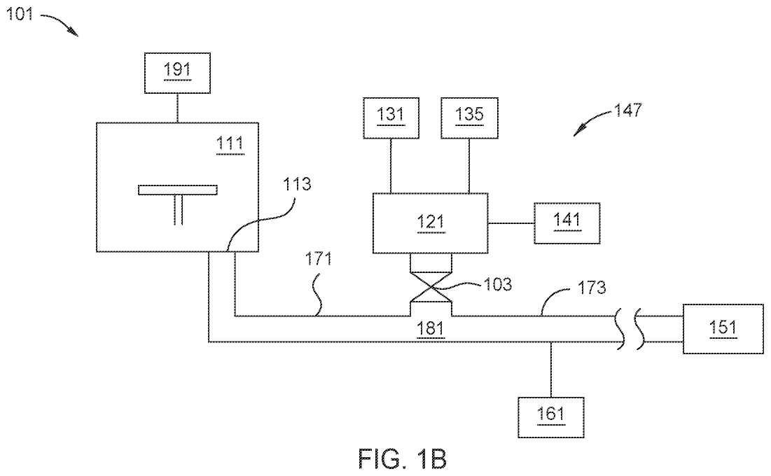

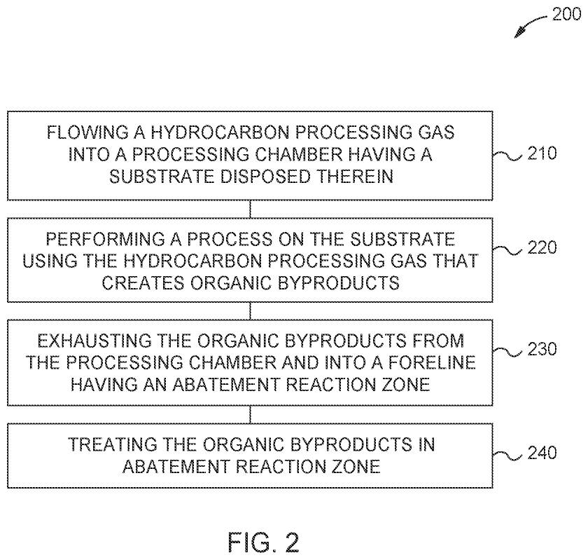

FIG. 1A is a schematic side view of a plasma processing system 100 having processing chamber 110 interfaced with an abatement system 146. The abatement system 146 is integrated with the forelines 170, 172 connected to a chamber exhaust port 112 of the processing chamber 110. The abatement system 146 includes an in-line plasma source (IPS) 120 that is connected in-line between the forelines 170, 172. FIG. 1B is a schematic side view of a plasma processing system 101 having processing chamber 111 interfaced with an abatement system 147. The abatement system 147 is integrated with the forelines 171, 173 connected to a chamber exhaust port 113 of the processing chamber 111. The abatement system 147 includes a remote plasma source (RPS) 121 that provides disassociated reactive gases to an abatement reaction zone 181 disposed in-line between the forelines 171, 173. Throughout the following description of FIGS. 1A and 1B, even reference numerals are shown in FIG. 1A while odd reference numerals are shown in FIG. 1B. Additionally, FIG. 2 depicts an effluent processing method 200 which comprises a plurality of operations for treating the effluent gases exiting the processing chambers 110, 111.

Generally, the plasma processing system 100 includes vacuum processing chamber 110 having a chamber exhaust port 112 connected to a foreline 170, 172. The forelines 170, 172 include the abatement reaction zone 180. In the example depicted in FIG. 1A, the abatement reaction zone 180 is defined within a foreline plasma source 120. The inlet of the foreline plasma source 120 is coupled to the foreline 170 while the outlet of the foreline plasma source 120 is coupled to the foreline 172. The foreline 172 is coupled to a vacuum pump 150 and optionally a pressure regulating module 160. The vacuum pump 150 may be coupled to a downstream exhaust facility (not shown). The vacuum pump 150 is generally utilized to evacuate the processing chamber 110, while the downstream exhaust facility generally includes scrubbers or other exhaust cleaning apparatus for preparing the effluent of the processing chamber 110 for atmospheric release. While only one vacuum pump 150 is shown in FIG. 1A, there may be a plurality of pumps coupled to the foreline 172 to draw the effluent towards the exhaust facility. In some embodiments, the optional pressure regulating module 160 injects a pressure regulating gas, such as a second inert gas, or other suitable gas as the foreline pressure may vary as the vacuum pump 150 may exhibit pressure variances of performance. The pressure regulating module 160 allows for the plasma within the plasma source 120 to be better controlled, and thereby provide more efficient abatement performance.

The foreline plasma source 120 receives reactive gases from an abating reagent gas source 134 that is coupled to the foreline 170 or to the foreline plasma source 120 itself. The foreline plasma source 120 also receives inert gas from an inert gas source 130. The inert gas source 130 is coupled to the foreline 170 or to the foreline plasma source 120 itself. The abating reagent gas source 134 may be a mixing chamber which provides a reagent gas mixture of two or more reagent gases. In some embodiments, the reagent gas source 134 may be a single reagent gas which may be energized to react with or otherwise assist converting the materials exiting the processing chamber 110 into a more environmentally and process equipment friendly composition. In other embodiments, the two or more reagent gases are mixed prior to entering their respective destinations. Additionally, the foreline plasma source 120 is coupled to an RF power source 140 that provides energy utilized to disassociate the reactive gases within the foreline plasma source 120.

The vacuum processing chamber 110 is configured to perform at least one integrated circuit manufacturing process, such as a deposition process, an etch process, a plasma treatment process, a preclean process, an ion implant process, or other integrated circuit manufacturing process. The vacuum processing chamber 110 is connected to a gas panel 190 that provides processing gases, such as deposition precursors, etchant or other processing gases into the processing region within the processing chamber 110 for processing substrates. The process performed in the vacuum processing chamber 110 may be plasma assisted, which disassociates the processing gases. For example, the process performed in the vacuum processing chamber 110 may be a thermal and/or plasma deposition process for depositing a carbon-based film material utilizing carbon-based processing gases. The processing region within the processing chamber 110 is evacuated through the exhaust port 112 through which processing gases and processing by-products are removed from the processing chamber 110 into the foreline 170.

Similarly, the plasma processing system 101 illustrated in FIG. 1B includes vacuum processing chamber 111 having a chamber exhaust port 113 connected to a foreline 171, 173. The forelines 171, 173 include the abatement reaction zone 181. In the example depicted in FIG. 1B, the abatement reaction zone 181 connected to the RPS 121.

The RPS 121 located close to the abatement reaction zone 181 to decrease the distance unstable radicals must travel to mix and react with the effluent. The RPS 121 may be controlled or isolated by use of a valve 103 located between the RPS 121 and the abatement reaction zone 181 on foreline 171. The distance between the RPS 121 and the abatement reaction zone 181 may be about 20 centimeters (cm) to 40 cm, such as about 25 cm to about 35 cm, such as about 30 cm. Typical valves include but not limited to, for example, butterfly, ball, v-ball, gate, globe, or angle valve suitable to isolate gas flow to and from the foreline 171. The valve 103 may be used for maintenance of the RPS 121, emergency shut down of the plasma abatement process system 101, control of flowrates, or other process operational needs.

The outlet of the RPS 121 provides a conduit for disassociated reactive gases to be injected into the abatement reaction zone 181. The outlet of the abatement reaction zone 181 is coupled to the foreline 173. The foreline 173 is coupled to a vacuum pump 151 and optionally a pressure regulating module 161. The vacuum pump 151 may be coupled to a downstream exhaust facility (not shown). The vacuum pump 151 is generally utilized to evacuate the processing chamber 111, while the downstream exhaust facility generally includes scrubbers or other exhaust cleaning apparatus for preparing the effluent of the processing chamber 111 for atmospheric release. While only one vacuum pump 151 is shown in FIG. 1B, there may be a plurality of pumps coupled to the foreline 173 to draw the effluent towards the exhaust facility. In some embodiments, the optional pressure regulating module 161 injects a pressure regulating gas, such as a second inert gas, or other suitable gas as the foreline pressure may vary as the vacuum pump 151 may exhibit pressure variances of performance. The pressure regulating module 161 allows for the plasma within the plasma source 121 to be better controlled, and thereby provide more efficient abatement performance.

An abating reagent gas source 135 is coupled to an inlet of the RPS 121. The abating reagent gas source 135 may be a mixing chamber which provides a reagent gas mixture of two or more reagent gases. In some embodiments, the reagent gas source 135 may be a single reagent gas which may be energized to react with or otherwise assist converting the materials exiting the processing chamber 111 into a more environmentally and process equipment friendly composition. In other embodiments, the two or more reagent gases are mixed prior to entering their respective destinations. Furthermore, inert gas from an inert gas source 131 is also coupled to an inlet of the RPS 121. The RPS 121 is coupled to an RF power source 141 that provides energy utilized to disassociate the reactive gases within the RPS 121. The disassociated reactive gases exit the outlet of RPS 121 through the valve 103 into the abatement reaction zone 181. The valve 103 can be shut to allow the RPS 121 to be service without taking the system 101 offline or to control the flowrate of the disassociated reactive gases.

The processing chamber 111 is configured to perform at least one integrated circuit manufacturing process, similar to that described with reference to vacuum processing chamber 110. The vacuum processing chamber 111 is connected to a gas panel 191 that provides processing gases, such as deposition precursors, etchant or other processing gases into the processing region within the processing chamber 111 for processing substrates. For example, the process performed in the vacuum processing chamber 111 may be a thermal and/or plasma deposition process for depositing a carbon-based film material utilizing carbon-based processing gases. The processing region within the processing chamber 111 is evacuated through the exhaust port 113 through which processing gases and processing by-products are removed from the processing chamber 111 into the foreline 171.

FIG. 2 is a flow diagram of a method 200 for treating effluent from a processing chamber, such as but not limited to the processing chambers 110, 111 described above utilizing an organic compound abatement system, such as but not limited to the abatement systems 146, 147 described above.

The method 200 begins at operation 210 by flowing a hydrocarbon processing gas into the processing chamber having a substrate disposed therein. Hydrocarbon processing gases may include, but not limited to, small saturated or unsaturated hydrocarbons including: methane (CH₄), ethane (C₂H₆), ethylene (C₂H₄), acetylene (C₂H₂), propane (C₃H₈), propene (C₃H₆), propyne (C₃H₄), butane (C₄H₁₀), butylene (C₄H₈), butadiene (C₄H₆), butyne (C₄H₆), or other small hydrocarbons containing 1 to 6 carbon atoms with varying degrees of unsaturation. In some embodiments, these hydrocarbon gases are flowed at a rate of about 50 sccm to about 2000 sccm while the substrate is maintained at temperature of about −200 degrees Celsius to about 600 degrees Celsius and at a chamber pressure of about 100 milliTorr to about 10,000 milliTorr.

At operation 220, a process is performed on the substrate using the hydrocarbon processing gas that creates an organic byproduct. In one example, the hydrocarbon processing gas provided from a gas panel to the processing chamber is used to deposit a carbon-containing film on the substrate. However, the method 200 may be beneficial to the treatment of an organic containing effluent generated by other types of processes performed in a substrate processing chamber, such as etching, annealing, and plasma treating, among others. In some examples, the hydrocarbon processing gases are energized, via a plasma, to deposit a carbon containing film on the substrate supported by a substrate support within the processing chamber.

The use of hydrocarbon processing gases at operation 220 produces organic byproducts which are pumped out of the processing chamber into the foreline as an organic effluent. In processes where the processing gases are silicon-free hydrocarbon processing gases, a silicon-free organic effluent is produced. In some examples, residual compounds comprising the organic effluent include organic gases such as, for example, propene (C₃H₆), acetylene (C₂H₂), or ethylene (C₂H₄), that are a byproduct of a carbon deposition process with the use of a hydrocarbon processing gas provided by the gas panel. In one example, the hydrocarbon processing gas is a silicon-free organic processing gas thereby creating silicon-free organic byproducts in the organic effluent. In other examples, organic effluent may include one or more organic byproducts comprising, but not limited to, residual deposition gases and reasonable plasma or thermal-decomposition products, possibly including atoms of oxygen, nitrogen, halogens, or other elements based on the requirements of the process requirements at operation 220.

At operation 230, the organic byproduct from the processing chamber is exhausted into a foreline having an abatement reaction zone. The organic byproducts (or organic gases) evacuated from the processing chamber into the foreline are also referred herein as organic effluent. The flowrates of the organic effluent entering the abatement reaction zone may be about 50 standard cubic centimeter per minute (sccm) to about 3000 sccm and be at a pressure in the range of about 50 milliTorr to about 10,000 milliTorr, in some examples.

As described above, the abatement reaction zone is within (or in-line with) the foreline. In one example, the abatement reaction zone is within a plasma source. For example as shown in FIG. 1A, the abatement reaction zone 180 is disposed within an IPS 120 that is downstream of a port in the foreline which provide reactive gases to abatement reaction zone 180. In another example as shown in FIG. 1B, the abatement reaction zone 181 is within the foreline downstream of a port coupled to the RPS 121 which provide disassociated reactive gases to abatement reaction zone 181.

At operation 240, the organic byproducts in the organic effluent are treated in the abatement reaction zone. Reactive gases are injected into the foreline and used to treat the organic byproducts in the organic effluent.

In one example, the organic effluent is treated by disassociating the organic byproduct and reactive gas in the IPS 120 which react to generate new, more benign, molecules from the organic effluent. For example, a reactive gas containing oxygen mixed with the organic effluent is disassociated in the IPS 120. Optionally, an inert gas may also be mixed with the reactive gas and the organic effluent in the IPS 120. The reactive gas and the optional inert gas flow mixture may be about 2 standard liter per min (slm) to about 40 slm for some embodiments, such as about 10 slm to about 40 slm, such as about 25 slm for embodiment using an IPS 120. It has been contemplated that lower or higher flowrates may be used depending on the process gases used in operation 220. Disassociated oxygen radicals from the reactive gas (e.g., neutral and charged oxygen atoms) break the bonds between the organic byproducts in the effluent to produce more benign molecules such as carbon dioxide, carbon monoxide, water vapor, and the like that are environmentally and equipment friendly. In some examples, the treated effluent may also contain oxygen-containing trace byproducts such as formaldehyde and formic acid.

The reactive gas is an oxygen-containing gas such as air, oxygen gas (O₂), ozone (O₃), water (H₂O), nitric oxide gas (NO), nitrogen dioxide (NO₂), or the like. In one embodiment, oxygen gas is utilized to treat the effluent by the creation of oxygen radicals through excitation of the oxygen gas via a plasma source.

When used, inert gas provided by an inert gas source is also energized with the reactive gas. Suitable inert gases include, but not limited to, argon, nitrogen, neon, helium, and krypton. Without being bound by theory, the energized inert gases extend the time in which the reactive gas remain disassociated, such as oxygen radicals described above, to enhance the conversion rate of the effluent compounds into a more benign form. For example, the use of argon gas simultaneously allows the conversion process to be more efficient and also allows for the unstable oxygen radicals expand the size of the abatement reaction zone without the oxygen recombining to form an oxygen gas. The percentage of inert gas to oxygen-containing gas can be about 0.5 percent to 1,000 percent, such as about 0.5 percent to about 500 percent, such as about 0.5 to about 250 percent or about 100 percent to about 500 percent.

In the above example, about 1.5 kilowatts (kW) to about 6 kW of power is utilized to disassociate the reactive gases within the IPS 120. In one example, 2 kW to about 6 kW, such as, about 3 kW to about 4.5 kW is provide to the IPS 120 to disassociate the reactive gases within the IPS 120.

In another example, the reactive gas and the optional inert gas may be provided to the abatement reaction zone 181 from a RPS 121 coupled to the foreline. The RPS 121 disassociates the reactive gas prior to entering the abatement reaction zone 181. The reactive gas and the optional inert gas flow mixture may be about 2 slm to about 10 slm for embodiments using an RPS 121. It has been contemplated that lower or higher flowrates may be used depending on the process gases used in operation 220.

In the above example, about 2 kW to 10 kW of power is utilized to disassociate the reactive gases within the RPS 121. In one example, 2 kW to about 8.5 kW, such as, about 6.9 kW to about 8.5 kW is provided to the RPS 121 to disassociate the reactive gases within the RPS 121 prior to introduction into the abatement reactive zone.

During treatment at operation 240, disassociated reactive gas is mixed with the organic effluent of the processing chamber in the abatement reaction zone. Oxygen gas that was previously disassociated via bombardment with energetic electrons propelled by RF fields, may now react with carbon atoms. Without being bound by theory, oxygen radicals may be utilized in the treatment of, for example, propene (C₃H₆) effluent and thereby form carbon dioxide and carbon monoxide as a result of disassociation of the propene effluent. For example, Equation (1) depicts the balanced stoichiometric formula of the conversion of a propene effluent thereby requiring a molecular ratio of 9 moles of oxygen gas to every 2 moles of propene.

$$2 {C}_{3} {H}_{6} + 9 {O}_{2} \to 6 {CO}_{2} + 6 {H}_{2} O \qquad Equation ( 1 )$$

Alternatively, Equation (2) may provide the molecular ratio necessary to complete disassociation of the propene effluent via use of oxygen radicals (O*) thereby requiring molecular ratio of 13 moles of oxygen radicals (or 7 moles of oxygen gas) to every 2 moles of propene.

$$2 {C}_{3} {H}_{6} + 13 {O}^{*} \to {CO}_{2} + 5 CO + 6 {H}_{2} O \qquad Equation ( 2 )$$

In yet another example, Equation (3) provides an ideal 1:1 molecular ratio (CO:CO₂) that may allow for complete disassociation of the propene effluent via use of oxygen radicals (O*) thereby requiring molecular ratio of 30 moles of oxygen radicals (or 15 moles of oxygen gas) to every 4 moles of propene.

$$4 {C}_{3} {H}_{6} + 30 {O}^{*} \to 6 {CO}_{2} + 6 CO + 12 {H}_{2} O \qquad Equation ( 3 )$$

Therefore, it is contemplated that a full disassociation of a propene effluent may be programmed into a chamber controller to deliver more or less oxygen gas or oxygen radicals by monitoring the effluent composition and adjusting the molecular ratio, via a gas flowrate or the like, accordingly.

The above was an example of oxygen radicals with a pure propene effluent. Similarly, a stoichiometric balance may be utilized with a molecular composition of effluent, such as with acetylene (C₂H₂), or ethylene (C₂H₄), to configure the molar ratios required for differing effluent components. In addition, the mole ratio may be utilized for an effluent that contains various compounds to determine or adjust the oxygen gas required for full disassociation of the effluent. As mentioned above, the amount of oxygen gas required for full disassociation of a mixed compound organic effluent may be programmed into a chamber controller. The disassociation of organic effluent is an exothermic reaction that may require personnel protection in the form of an external heat guard placed along the abatement reaction zone or plasma portions of the foreline upstream and downstream of the abatement reaction zone.

Treatment of the organic effluent has proven beneficial to the longevity of equipment lifespan by reducing carbon-byproduct deposition on downstream equipment. For example, in processes having heavy organic byproducts, the service life of vacuum equipment, such as a vacuum pump, is significantly extended.

The effluent processing method 200 of FIG. 2 may be performed at the initiation sequence of the deposition process of the chamber. Therefore, the IPS 120 or RPS 121 of FIG. 1A or FIG. 1B would initiate the creation and introduction of oxygen radicals into the foreline before the deposition process has begun. This ensures the conversion of the initial effluent drawn from the processing chamber. The effluent processing method 200 may be programmed into a controller to simultaneously introduce the organic processing gas into the processing chamber and initiate the IPS or RPS. Conversely, the effluent processing method 200 of FIG. 2 may be operated for a period of time, for example, about 1 second to about 15 seconds, after the processing chamber is shut down to ensure any and all effluent or precursor gases are converted into a more benign form.

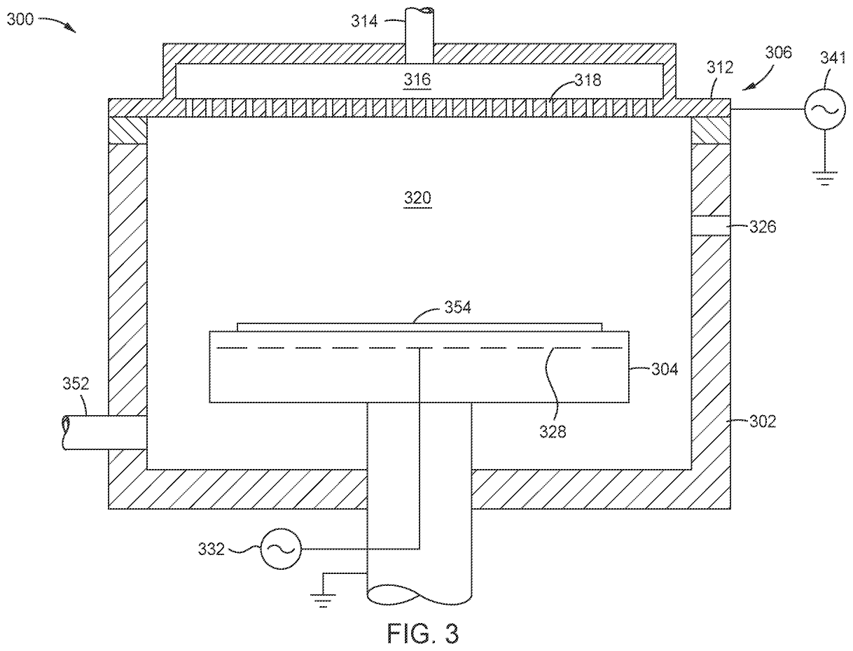

The effluent processing method 200 described above may be performed to treat organic effluent exiting a variety of processing chambers, including Plasma Enhanced Chemical Vapor Deposition (PECVD) chambers, Chemical Vapor Deposition (CVD) chambers, Physical Vapor Deposition (PVD) chambers, among others. FIG. 3 illustrates an exemplary PECVD chamber 300 suitable to depositing a carbon containing film on a substrate using a hydrocarbon processing gas that produces an organic effluent that can be treated within the foreline utilizing the methods described above. The PECVD chamber 300 includes a chamber body 302, a substrate support 304 with an electrode 328 disposed therein, the substrate support 304 disposed inside the chamber body 302, and a lid assembly 306 coupled to the chamber body 302 and enclosing the substrate support 304 in a processing region 320. The lid assembly 306 includes a gas distributor 312. A substrate 354 is transferred to the processing region 320 through an opening 326 formed in the chamber body 302. The gas distributor 312 features openings 318 for admitting process gases into the processing region 320. The process gases may be supplied to the PECVD chamber 300 via a conduit 314, and the process gases may enter a gas mixing region 316 prior to flowing through the openings 318. An exhaust port 352 is formed in the chamber body 302 at a location below the substrate support 304. The exhaust port 352 may be connected to a vacuum pump (not shown) to remove unreacted species and by-products from the PECVD chamber 300. The gas distributor 312 may be coupled to an electric power source 341, such as an RF generator. Similarly, substrate support 304 may be coupled to an electric power source 332, such as an RF generator or a DC power source.

All numerical values are “about” or “approximately” the indicated value, and take into account experimental error and variations that would be expected by a person having ordinary skill in the art.

While the foregoing is directed to embodiments of the present disclosure, other and further embodiments of the disclosure may be devised without departing from the basic scope thereof, and the scope thereof is determined by the claims that follow.

Certain embodiments and features have been described using a set of numerical minimum values and a set of numerical maximum values. It should be appreciated that ranges including the combination of any two values, e.g., the combination of any minimum value with any maximum value, the combination of any two minimum values, and/or the combination of any two maximum values are contemplated unless otherwise indicated. Certain minimum values, maximum values, and ranges appear in one or more claims below.

What is claimed is:

1. A method for treating effluent from a processing chamber, the method comprising:
flowing a hydrocarbon processing gas into a processing chamber for processing a substrate;
performing a process on the substrate using the hydrocarbon processing gas that creates organic byproducts;
exhausting the organic byproducts from the processing chamber into a foreline having an abatement reaction zone; and
treating the organic byproducts in the abatement reaction zone powered by a plasma source, wherein treating the organic byproducts comprises;
mixing a disassociated oxygen-containing gas and the organic byproducts in the abatement reaction zone; and
forming at least carbon monoxide and carbon dioxide from a mixture of the disassociated oxygen-containing gas and the organic byproducts.

2. The method of claim 1, wherein the hydrocarbon processing gas comprises methane, ethane, ethylene, acetylene, propane, propene, propyne, butane, butylene, butadiene, butyne, or a combination thereof.

3. The method of claim 1, wherein exhausting the organic byproducts from the processing chamber is performed by a vacuum pump.

4. The method of claim 1, wherein treating the organic byproducts further comprises powering the plasma source with RF power of about 2 kilowatts to about 10 kilowatts.

5. The method of claim 4, wherein the plasma source comprises an in-line plasma source.

6. The method of claim 4, wherein the RF power that powers the plasma source is about 2 kilowatts to about 6 kilowatts.

7. The method of claim 6, wherein the RF power that powers the plasma source is about 3 kilowatts to about 4.5 kilowatts.

8. The method of claim 4, wherein the plasma source comprises a remote plasma source.

9. The method of claim 8, wherein the RF power that powers the plasma source is about 2 kilowatts to about 8.5 kilowatts.

10. The method of claim 9, wherein the RF power that powers the plasma source is about 6.9 kilowatts to about 8.5 kilowatts.

11. The method of claim 1, wherein the disassociated oxygen-containing gas comprises an oxygen gas selected from the group consisting of air, ozone, oxygen gas, nitric oxide gas, and nitrogen dioxide.

12. The method of claim 1, wherein the disassociated oxygen-containing gas comprises oxygen gas.

13. The method of claim 1, wherein treating the organic byproducts in the abatement reaction zone further comprises mixing the disassociated oxygen-containing gas and the organic byproducts with an inert gas, the inert gas selected from the group consisting of argon, neon, nitrogen, helium, and krypton.

14. The method of claim 13, wherein a ratio of the inert gas to the disassociated oxygen-containing gas is from about 0.5 percent to about 1000 percent.

15. The method of claim 12, wherein the organic byproducts comprise propene, ethylene or decomposition products of small hydrocarbons with varying degrees of unsaturation that are caused by plasma or thermal energy.

16. The method of claim 15, wherein the organic byproducts comprise propene.

17. The method of claim 16, further comprising flowing the disassociated oxygen-containing gas into the abatement reaction zone, a molar ratio of the disassociated oxygen-containing gas to the organic byproducts being about 2:9.

18. The method of claim 1, further comprising converting the organic byproducts into a fluid comprising carbon dioxide and carbon monoxide.

19. The method of claim 1, further comprising: exhausting an effluent containing the organic byproducts to the abatement reaction zone at a flow rate of about 50 sccm to about 3000 sccm and at a pressure of about 50 milliTorr to about 10,000 milliTorr.

20. A vacuum chamber abatement system comprising:
a vacuum chamber having an interior volume;
an exhaust port coupled to the interior volume;
a foreline connecting the exhaust port to a remote plasma source, the remote plasma source disposed about 20 cm to about 40 cm in length from the foreline;
a valve disposed between the remote plasma source and the foreline;
a vacuum pump coupled to the foreline, the remote plasma source disposed upstream of the vacuum pump;
an RF power source coupled to the remote plasma source;
an inert gas source coupled to the remote plasmas source;
an oxygen gas source coupled to the remote plasma source;
a foreline pressure gas source coupled to the foreline disposed between the remote plasma source and the vacuum pump; and
a controller coupled to the vacuum chamber configured to:
flow a hydrocarbon precursor gas into the vacuum chamber for carbon deposition on a substrate within;
perform a carbon deposition process on the substrate that creates organic byproducts, the organic byproducts being silicon-free and comprising propene;
exhaust the organic byproducts from the vacuum chamber and into the foreline through the exhaust port; and
treat the organic byproducts in the foreline, wherein treating the organic byproducts comprises;
flowing an oxygen gas into the remote plasma source at a molar ratio of 2:9 (oxygen gas:organic byproduct);
mixing an argon gas with the oxygen gas at a ratio of 0.5 percent to 250 percent (inert gas:oxygen gas);
forming a plasma to create oxygen radicals and argon radicals;
mixing the oxygen radicals and argon radicals with the organic byproducts in the foreline; and
disassociating the organic byproducts into a fluid comprising carbon monoxide and carbon dioxide.
